(19) United States
(12) Patent Application Publication
(10) Pub. No.: US 2009/0159326 A1
(43) Pub. Date: Jun. 25, 2009

(54) S-TURN VIA AND METHOD FOR REDUCING SIGNAL LOSS IN DOUBLE-SIDED PRINTED WIRING BOARDS

(76) Inventor: Richard Mellitz, Irmo, SC (US)

Correspondence Address: BUCKLEY, MASCHOFF & TALWALKAR LLC, 50 LOCUST AVENUE, NEW CANAAN, CT, 06840, US

(21) Appl. No.: 11/960,398

(22) Filed: Dec. 19, 2007

(51) Int. Cl. H05K 1/11; G06F 17/50

(52) U.S. Cl. 174/266; 716/1

(57) ABSTRACT

Embodiments of the invention include a Printed Wiring Board (PWB) having a first via connected to a top-side signal source, a second via connected to a bottom-side signal destination, and a third via connected to the first via on a lower signal layer of the PWB and further connected to the second via on an upper signal layer of the PWB. In embodiments of the invention, the third via is referred to as an S-Turn via. The S-Turn PWB routing configuration advantageously reduces reflections causes by via stubs at Multi-Giga Hertz (MGH) frequencies. Other embodiments are described.

### FIELD

The invention relates generally to Printed Wiring Board (PWB) technology, and more particularly, but without limitation, to an S-Turn via structure in a double-sided multi-layered PWB.

### BACKGROUND

Multi-layered Printed Wiring Boards (PWB's) are generally known in the art. In the case of a double-sided PWB, such as a mid-plane, the double-sided PWB is configured to receive connector pins or other components on both a top side and a bottom side of the PWB during assembly. A signal having a source on a top side of the PWB and a destination on a bottom side of the PWB is typically routed through a first Plated-Through-Hole (PTH) via, a trace in a routing layer of the PWB, and a second PTH via.

A signal path that follows such a routing does not use certain portions of the first PTH via and the second PTH via. The unused portions of the first PTH via and the second PTH via are referred to as via stubs. For high-frequency signals, for example Multi-Giga Hertz (MGH) signals, such via stubs can cause reflections at harmonic frequencies of the signal and create an impedance mismatch that results in a loss of signal strength and/or signal distortion.

A conventional method for eliminating or reducing the effect of via stubs is to remove via stubs by back-drilling. This method has many disadvantages, however. For instance, back-drilling increases the number of PWB fabrication steps, reduces PWB fabrication yield, and increases PWB fabrication cost. Moreover, back-drilling may not be practical for double-sided PWB's. Improved features and/or routing methods are therefore needed to address the problem presented by via stubs in double-sided PWB's.

### BRIEF DESCRIPTION OF THE DRAWINGS

The present invention will be more fully understood from the detailed description below and the accompanying drawings, wherein:

FIGS. 1A-1D are cross-section illustrations of multi-layered PWB's;

FIG. 2 is a cross-section illustration of a multi-layered PWB, according to an embodiment of the invention;

FIG. 3 is a flow diagram of a PWB routing process, according to an embodiment of the invention;

FIG. 4A is a graph of signal properties in a multi-layered PWB, according to a simulation of a PWB routing in the conventional art; and

FIG. 4B is a graph of signal properties in a multi-layered PWB, according to a simulation of a PWB routing that is consistent with an embodiment of the invention.

### DETAILED DESCRIPTION

Embodiments of the invention will now be described more fully with reference to the figures, in which embodiments of the invention are shown. This invention may, however, be embodied in many different forms and should not be construed as limited to the embodiments set forth herein. Rather these embodiments are provided so that this disclosure will be thorough and complete, and will fully convey the scope of the invention to those skilled in the art. The illustrated features of PWB's are not drawn to scale.

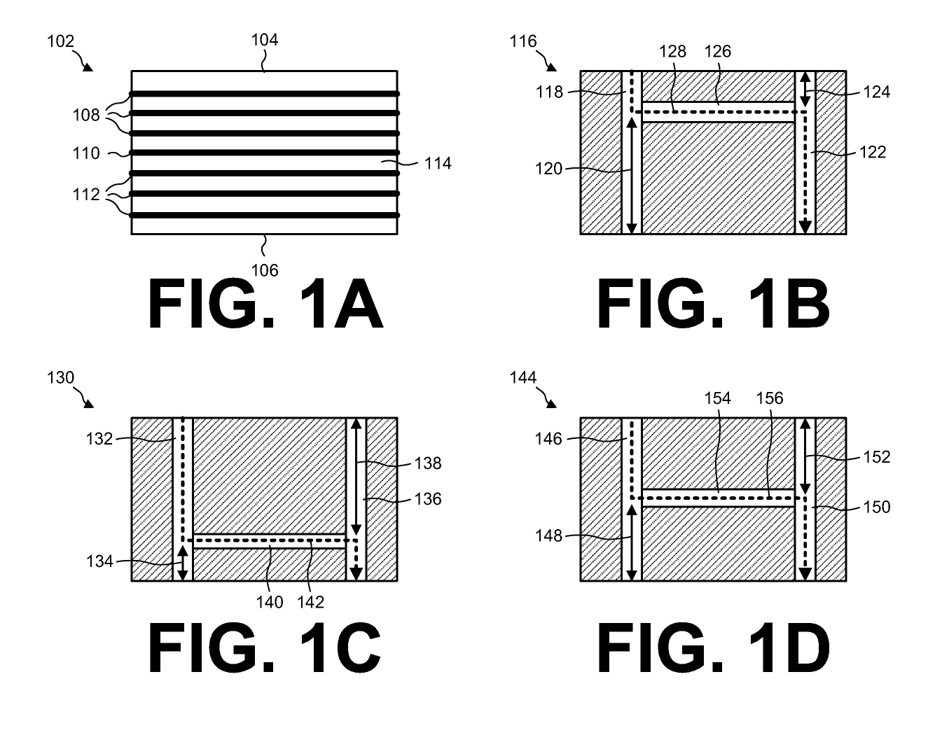

FIGS. 1A-1D are cross-section illustrations of multi-layered PWB's.

FIG. 1A illustrates a multi-layered PWB 102 having a top side 104, a bottom side 106, three upper signal layers 108, a middle signal layer 110, and three lower signal layers 112. Each of the signal layers are separated by an insulation layer 114. Each of the signal layers may include one or more conductive traces, for example copper traces, which are used as part of a signal path.

Variations to the multi-layered PWB illustrated in FIG. 1A are possible. For instance, a multi-layered PWB may have any number of upper and lower signal layers.

The PWB configurations illustrated in FIGS. 1B, 1C, and 1D are consistent with the structure of the PWB illustrated in FIG. 1A and described, together with possible variations, above.

FIG. 1B illustrates a portion of a multi-layered PWB 116 having a via 118 coupled to a trace 126 and a via 122. The trace 126 is on an upper signal layer (not shown). A signal path 128 extends from a top portion of via 118 through the trace 126 to a bottom portion of via 122. Via stub 120 exists in an unused portion of via 118. Via stub 122 exists in an unused portion of via 122. Via stub 120 may be sufficiently long to cause undesirable reflections that interfere with a signal on the signal path 128.

FIG. 1C illustrates a portion of a multi-layered PWB 130 having a via 132 coupled to a trace 140 and a via 136. The trace 140 is on a lower signal layer (not shown). A signal path 142 extends from a top portion of via 132 through the trace 140 to a bottom portion of via 136. Via stub 134 exists in an unused portion of via 132. Via stub 138 exists in an unused portion of via 136. Via stub 138 may be sufficiently long to cause undesirable reflections that interfere with a signal on the signal path 142.

FIG. 1D illustrates a portion of a multi-layered PWB 144 having a via 146 coupled to a trace 154 and a via 150. The trace 154 is on a middle signal layer (not shown). A signal path 156 extends from a top portion of via 146 through the trace 154 to a bottom portion of via 150. Via stub 148 exists in an unused portion of via 146. Via stub 152 exists in an unused portion of via 150. Via stubs 148 and 152 may be sufficiently long to cause undesirable reflections that interfere with a signal on the signal path 156.

FIGS. 1B, 1C, and 1D thus illustrate PWB structures having potentially problematic via stubs.

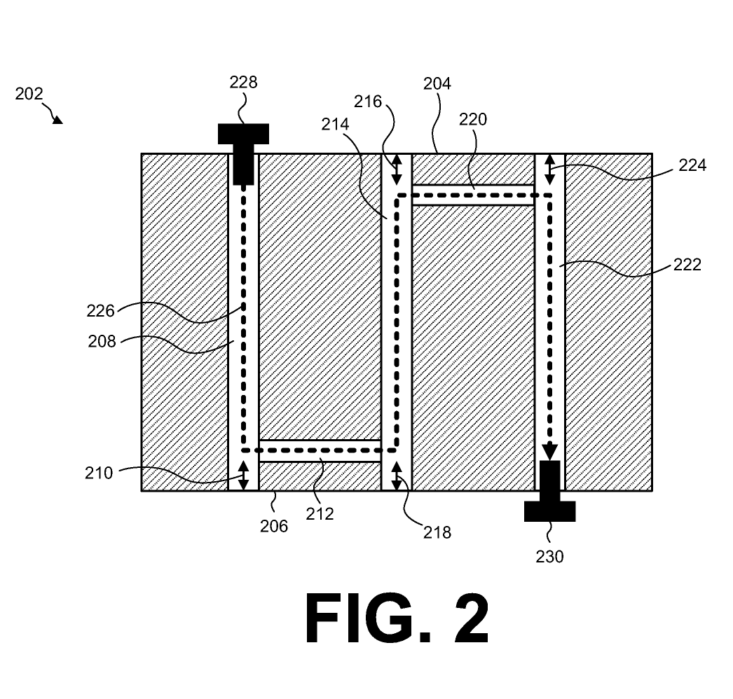

FIG. 2 is a cross-section illustration of a multi-layered PWB, according to an embodiment of the invention. The multi-layered PWB illustrated in FIG. 2 is a double-sided PWB, for instance a mid-plane.

As illustrated in FIG. 2, a PWB 202 includes a top side 204 and a bottom side 206. The PWB 202 further includes a via 208, a trace 212, a via 214, a trace 220, and a via 222. The via 208 is configured to receive a connector pin 228, for example a Press-Fit Pin (PFP), on the top side 204. The via 222 is configured to receive a connector pin 230, for example a PFP, on the bottom side 206. The trace 212 is on a lower signal layer (not shown). The trace 220 is on an upper signal layer (not shown).

The connector pin 228 is associated with a signal source, and the connector pin 230 is associated with a signal destination. A signal path 226 extends from the connector pin 228 through the via 208, the trace 212, the via 218, the trace 220, and the via 222, terminating at the connector pin 230. The signal path 226 thus forms an S-Turn in the PWB 202, and the via 214 may be referred to as an S-Turn via.

Via stub 210 exists in an unused portion of the via 208. Via stubs 216 and 218 exist in unused portions of via 214. Via stub 224 exists in an unused portion of via 222. Each of the via stubs 210, 216, 218, and 224 are sufficiently short so that a signal on the signal path 226 is not substantially attenuated or otherwise distorted by via stub reflections.

Variations to the PWB configuration illustrated in FIG. 2 are possible. For instance, the via 208 may be configured to connect to a component other than connector pin 228. Likewise, the via 222 may be configured to connect to a component other than connector pin 230. In addition, the via 218 may be a buried via rather than the illustrated PTH via. In a buried via configuration, the buried via may not include via stubs 216 and 218.

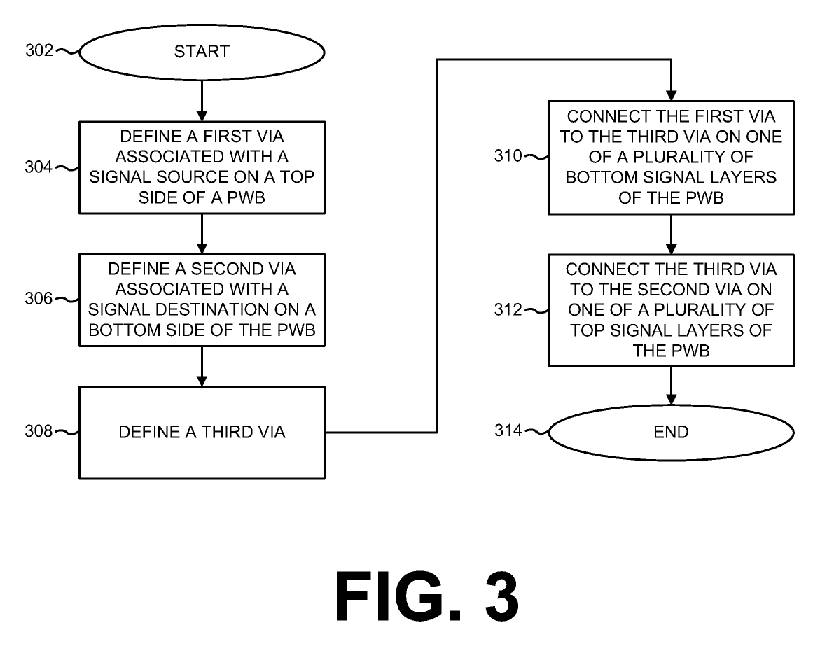

FIG. 3 is a flow diagram of a PWB routing process, according to an embodiment of the invention. The PWB routing process illustrated in FIG. 3 and described below is especially applicable to a double-sided multi-layered PWB.

After starting in step 302, the process defines a first via associated with a signal source on a top side of a PWB in step 304. Then, in step 306, the process defines a second via associated with a signal destination on a bottom side of the PWB. The process defines a third via in step 308. The process connects the first via to the third via on one of a plurality of bottom signal layers of the PWB in step 310, and then connects the third via to the second via on one of a plurality of top signal layers of the PWB in step 312 before terminating in step 314. Connections on signal layers may be accomplished using conductive traces, for example copper traces.

A result of the routing process illustrated in FIG. 3 and described above is a signal path having an S-Turn shape. The third via can thus be referred to as the S-Turn via.

Variations to the process described with reference to FIG. 3 are possible. For instance, in one embodiment, each of the first, second, and third vias are defined as PTH vias in steps 304, 306, and 308, respectively. In an alternative embodiment, the third via is defined as a buried via. Moreover, in one embodiment the first via is configured to accept a connector pin, such as a PFP, on the top side of the PWB in step 304, and the second via is configured to accept a connector pin, such as a PFP, on the bottom side of the PWB in step 306. But in alternative embodiments, the first via and/or the second via could be configured to accept a component other than a connector pin.

The routing process illustrated in FIG. 3 and described above could be performed manually. Alternatively, the routing process illustrated in FIG. 3 and described above could be automatically or semi-automatically, for example by an automated PWB routing software tool. In the case of automated or semi-automated operation, the process could be implemented using processor-executable code, and the processor-executable code could be stored on processor-readable storage medium, such as a hard drive or Compact Disc (CD). Moreover, the routing process illustrated in FIG. 3 and described above could be implemented in hardware, or in a combination of hardware and software.

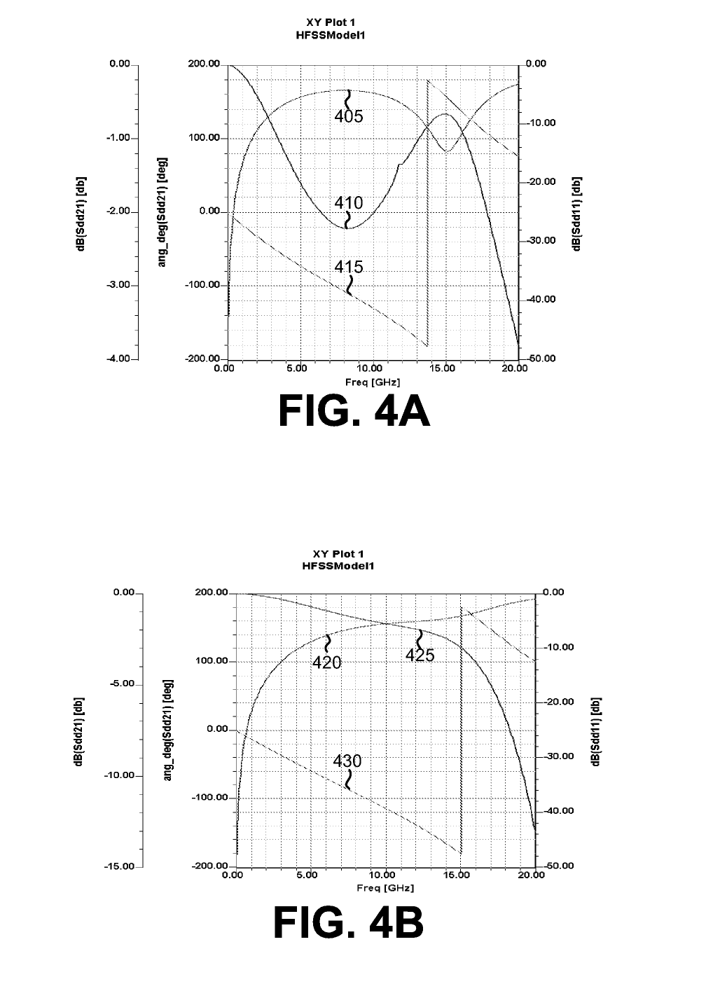

FIG. 4A is a graph of signal properties in a multi-layered PWB, according to a simulation of a PWB routing in the conventional art. FIG. 4A illustrates the dB magnitude of return loss in curve 405, the dB magnitude of insertion loss in curve 410, and the phase in curve 415. FIG. 4B is a graph of signal properties in a multi-layered PWB, according to a simulation of a PWB routing that is consistent with the embodiment illustrated in FIG. 2. FIG. 4B illustrates the dB magnitude of return loss in curve 420, the dB magnitude of insertion loss in curve 425, and the phase in curve 430. A comparison of the two graphs thus illustrates that a PWB that is constructed in accordance with an embodiment of the invention eliminates a predicted signal attenuation that is centered at approximately 8 GHz.

It will be apparent to those skilled in the art that modifications and variations can be made without deviating from the spirit or scope of the invention. For example, the PWB structure and method disclosed herein are applicable various configurations of PWB's having two or more signal routing layers. Thus, it is intended that the present invention cover any such modifications and variations of this invention provided they come within the scope of the appended claims and their equivalents.

1. A multi-layered Printed Wiring Board (PWB) comprising:
a first via configured to receive a signal on a top surface of the multi-layered PWB, the first via extending from the top surface of the multi-layered PWB to a bottom surface of the multi-layered PWB;
a first signal trace coupled to the first via, the first signal trace being on a lower signal layer of the multi-layered PWB, the lower signal layer being relatively far from the top surface of the multi-layered PWB and relatively close to the bottom surface of the multi-layered PWB;
a second via coupled to the first signal trace, the second via extending from the top surface of the multi-layered PWB to the bottom surface of the multi-layered PWB;
a second signal trace coupled to the second via, the second signal trace being on an upper signal layer of the multi-layered PWB, the upper signal layer being relatively close to the top surface of the multi-layered PWB and relatively far from the bottom surface of the multi-layered PWB; and
a third via coupled to the second signal trace, the third via configured to deliver the signal to a bottom surface of the multi-layered PWB, the third via extending from the top surface of the multi-layered PWB to the bottom surface of the multi-layered PWB.

2. The multi-layered PWB of claim 1, wherein the multi-layered PWB is a mid-plane.

3. The multi-layered PWB of claim 1, wherein the first via is configured to receive a first connector pin on the top surface of the multi-layered PWB and the third via is configured to receive a second connector pin on the bottom surface of the multi-layered PWB.

4. The multi-layered PWB of claim 1, wherein the second via is not connected to a third signal trace.

5. The multi-layered PWB of claim 1, wherein the second via is a buried via.

6. The multi-layered PWB of claim 1, wherein the second via is a plated-through-hole (PTH) via.

7. The multi-layered PWB of claim 1, wherein the first signal trace and the second signal trace include copper.

8. A processor-readable medium having processor-executable code stored thereon, the processor-executable code configured to perform a method, the method comprising:
defining a first via associated with a source of a signal on a top side of a multi-layered PWB, the first via extending from the top surface of the multi-layered PWB to a bottom surface of the multi-layered PWB;
defining a second via associated with a destination of the signal a bottom side of the multi-layered PWB, the second via extending from the top surface of the multi-layered PWB to the bottom surface of the multi-layered PWB;
defining a third via, the third via extending from the top surface of the multi-layered PWB to the bottom surface of the multi-layered PWB;
connecting the first via to the third via on one of a plurality of lower signal layers of the PWB, the plurality of lower signal layers being relatively far from the top side of the multi-layered PWB and relatively close to the bottom side of the multi-layered PWB; and
connecting the third via to the second via on one of a plurality of upper signal layers of the PWB, the plurality of upper signal layers being relatively close to the top side of the multi-layered PWB and relatively far from the bottom side of the multi-layered PWB.

9. The processor-readable medium of claim 8, wherein defining the first via includes configuring the first via to receive a first connector pin on the top surface of the multi-layered PWB.

10. The processor-readable medium of claim 8, wherein defining the first via includes configuring a plated-through-hole (PTH) via.

11. The processor-readable medium of claim 8, wherein defining the second via includes configuring the second via to receive a second connector pin on the bottom surface of the multi-layered PWB.

12. The processor-readable medium of claim 8, wherein defining the second via includes configuring a plated-through-hole (PTH) via.

13. The processor-readable medium of claim 8, wherein defining the third via includes defining a buried via.

14. The processor-readable medium of claim 8, wherein connecting the first via to the third via includes defining a signal trace on a selected one of the plurality of lower signal layers.

15. The processor-readable medium of claim 8, wherein connecting the third via to the second via includes defining a signal trace on a selected one of the plurality of upper signal layers.
